(19) United States
(12) Patent Application Publication
(10) Pub. No.: US 2019/0189233 A1
(43) Pub. Date: Jun. 20, 2019

(54) SHIFT REGISTER UNIT AND DRIVING METHOD THEREOF, GATE DRIVING CIRCUIT, ARRAY SUBSTRATE, DISPLAY APPARATUS

(71) Applicants: BEIJING BOE DISPLAY TECHNOLOGY CO., LTD., Beijing (CN); BOE TECHNOLOGY GROUP CO., LTD., Beijing (CN)

(72) Inventor: Qiujie SU, Beijing (CN)

(21) Appl. No.: 16/304,738

(22) PCT Filed: Feb. 8, 2018
(86) PCT No.: PCT/CN2018/075745

§ 371 Date: Nov. 27, 2018

(30) Foreign Application Priority Data
Jul. 21, 2017 (CN) 201710601007.2

(51) Int. Cl. G11C 19/28; G09G 3/20

(52) U.S. Cl. CPC G11C 19/287; G09G 3/20; G09G 2310/0286; G09G 2300/0426; G09G 2310/08; G09G 2300/0408

(57) ABSTRACT

There are disclosed in the present disclosure a shift register unit and a driving method thereof, a gate driving circuit, an array substrate and a display apparatus. The shift register unit includes: an input sub-circuit for receiving an input signal from an input terminal, outputting the input signal to the pull-up node, and outputting a pull-up signal through the pull-up node; a first output sub-circuit for receiving the pull-up signal and a first clock signal, and outputting a first output signal from a first output signal terminal according to the pull-up signal and the first clock signal; a second output sub-circuit for receiving the pull-up signal and a second clock signal, and outputting a second output signal from a second output signal terminal according to the pull-up signal and the second clock signal; a storage sub-circuit for storing the pull-up signal.

### CROSS-REFERENCE TO RELATED APPLICATION

The present application claims the priority of a Chinese patent application No. 201710601007.2 filed on Jul. 21, 2017. Herein, the content disclosed by the Chinese patent application is incorporated in full by reference as a part of the present application.

### TECHNICAL FIELD

The present disclosure relates to a field of display technique, in particular to a shift register unit, a driving method thereof, a gate driving circuit, an array substrate, and a display apparatus.

### BACKGROUND

Gate driver on array (GOA) technique is a technique of integrating a gate driving circuit into an array substrate to take the place of a gate driving chip, thereby reducing power consumption and cost. By taking the cost factor into consideration, the current display panel industry starts to adopt a GOA structure to implement driving of the display panel. In recent years, this trend becomes sharp increasingly in recent years.

The GOA structure means to fabricate a gate driving circuit on an array substrate by using several thin film transistors (TFTs) and capacitors. It is essentially a shift register, and would output a high level sequentially along with a clock signal, so as to open a corresponding gate line.

### SUMMARY

In view of this, a purpose of the present disclosure is to provide a shift register unit and method driving method thereof, a gate driving circuit, an array substrate and a display apparatus.

Based on the above purpose, there is provided according to a first aspect of an embodiment of the present disclosure a shift register unit, comprising:

an input sub-circuit, wherein a first terminal of the input sub-circuit is connected to an input terminal and a second terminal of the input sub-circuit is connected to a pull-up node, for receiving an input signal from the input terminal, outputting the input signal to the pull-up node, and outputting a pull-up signal through the pull-up node;

a first output sub-circuit, wherein a first terminal of the first output sub-circuit is connected to a first output signal terminal, a second terminal of the first output sub-circuit is connected to a first clock signal terminal, and a third terminal of the first output sub-circuit is connected to the pull-up node, for receiving the pull-up signal and a first clock signal, and outputting a first output signal from the first output signal terminal according to the pull-up signal and the first clock signal;

a second output sub-circuit, wherein a first terminal of the second output sub-circuit is connected to a second output signal terminal, a second terminal of the second output sub-circuit is connected to a second clock signal terminal, and a third terminal of the second output sub-circuit is connected to the pull-up node, for receiving the pull-up signal and a second clock signal, and outputting a second output signal from the second output signal terminal according to the pull-up signal and the second clock signal;

a storage sub-circuit, wherein a first terminal of the storage sub-circuit is connected to the pull-up node, a second terminal of the storage sub-circuit is connected to the second output sub-circuit, for storing the pull-up signal.

In some embodiments, the shift register unit as described above further comprises: a first reset sub-circuit, wherein a first terminal of the first reset sub-circuit is connected to the pull-up node, a second terminal of the first reset sub-circuit is connected to a first reset terminal, and a third terminal of the first reset sub-circuit is connected to a reset voltage terminal, for receiving a first reset signal from the first reset terminal, and resetting the pull-up node according to the first reset signal.

In some embodiments, the shift register unit as described above further comprises: a second reset sub-circuit, wherein a first terminal of the second reset sub-circuit is connected to the first output sub-circuit, a second terminal of the second reset sub-circuit is connected to a second reset terminal, and a third terminal of the second reset sub-circuit is connected to a reset voltage terminal, for receiving a second reset signal from the second reset terminal, and resetting the first output sub-circuit according to the second reset signal.

In some embodiments, the shift register unit as described above further comprises: a third reset sub-circuit, wherein a first terminal of the third reset sub-circuit is connected to the second output sub-circuit, a second terminal of the third reset sub-circuit is connected to a third reset terminal, and a third terminal of the third reset sub-circuit is connected to a reset voltage terminal, for receiving a third reset signal from the third reset terminal, and resetting the second output sub-circuit according to the third reset signal.

In some embodiments, the input sub-circuit comprises an input transistor, wherein a control electrode and a first electrode of the input transistor are connected to the input terminal and receive the input signal through the input terminal, and a second electrode of the input transistor is connected to the pull-up node.

In some embodiments, the first output sub-circuit comprises a first output transistor, wherein a control electrode of the first output transistor is connected to the pull-up node, a first electrode of the first output transistor is connected to the first clock signal terminal and receives the first clock signal, and a second electrode of the first output transistor is connected to the first output signal terminal and outputs the first output signal.

In some embodiments, the second output sub-circuit comprises a second output transistor, wherein a control electrode of the second output transistor is connected to the pull-up node, a first electrode of the second output transistor is connected to the second clock signal terminal and receives the second clock signal, and a second electrode of the second output transistor is connected to the second output signal terminal and outputs the second output signal.

In some embodiments, the storage sub-circuit comprises a capacitor, wherein a first terminal of the capacitor is connected to the pull-up node, and a second terminal of the capacitor is connected to the second output signal terminal.

In some embodiments, the first reset sub-circuit comprises a first reset transistor, wherein a control electrode of the first reset transistor is connected to the first reset terminal and receives the first reset signal, a first electrode of the first reset transistor is connected to the storage sub-circuit, and a second electrode of the first reset transistor is connected to a reset voltage terminal and receives a reset voltage signal; and/or, the second reset sub-circuit comprises a second reset transistor, wherein a control electrode of the second reset transistor is connected to the second reset terminal and receives the second reset signal, a first electrode of the second reset transistor is connected to the first output signal terminal, and a second electrode of the second reset transistor is connected to the reset voltage terminal and receives the reset voltage signal; and/or, the third reset sub-circuit comprises a third reset transistor, wherein a control electrode of the third reset transistor is connected to the third reset terminal and receives the third reset signal, a first electrode of the third reset transistor is connected to the second output signal terminal, and a second electrode of the third reset transistor is connected to the reset voltage terminal and receives the reset voltage signal.

In some embodiments, a noise reduction sub-circuit is disposed between the input sub-circuit and the first output sub-circuit, and/or, a second noise reduction sub-circuit is disposed between the input sub-circuit and the second output sub-circuit.

In some embodiments, the first reset signal and the third reset signal are a same reset signal.

According to a second aspect of an embodiment of the present disclosure, there is provided a driving method of a shift register unit for driving the shift register unit as described above, comprising:

outputting a pull-up signal to a first output sub-circuit and a second output sub-circuit through an input sub-circuit when an input signal is at a turn-on level;

in a first period of time, a first clock signal is at a turn-on level, and a first output sub-circuit outputs a first output signal;

in a second period of time, the first clock signal and a second clock signal are at a turn-on level, a second output sub-circuit outputs a second output signal, and the first output sub-circuit continuously outputs the first output signal.

In some embodiments, the driving method further comprises: in a third period of time, a second reset signal is at a turn-on level, and resetting of the first output signal is completed.

In some embodiments, the driving method further comprises: in a fourth period of time, a first reset signal and a third reset signal are at a turn-on level, and resetting of the pull-up signal and the second output signal is completed.

In some embodiments, the first reset signal and the third reset signal are a same reset signal.

According to a third aspect of an embodiment of the present disclosure, there is provided a gate driving circuit, comprising at least two shift register units connected in cascades as described above.

An input signal terminal of a N-th stage of shift register unit is connected to a second output signal terminal of a (N−1)-th stage of shift register unit, a first clock signal terminal and a second clock signal terminal of the N-th stage of shift register unit are connected to a first clock signal and a second clock signal respectively, a first reset signal terminal and a third reset signal terminal of the N-th stage of shift register unit are connected to a second output signal terminal of a (N+1)-th stage of shift register unit, and a second reset signal terminal of the N-th stage of shift register unit is connected to a first output signal terminal of the (N+1)-th stage of shift register unit.

In some embodiments, an input signal terminal of the (N+1)-th stage of shift register unit is connected to a second output signal terminal of the N-th stage of shift register unit, a first clock signal terminal and a second clock signal terminal of the (N+1)-th stage of shift register unit are connected to a third clock signal and a fourth clock signal respectively, a first reset signal terminal and a third reset signal terminal of the (N+1)-th stage of shift register unit is connected to a second output signal terminal of a (N+2)-th stage of shift register unit, and a second reset signal terminal of the (N+1)-th stage of shift register unit is connected to a first output signal terminal of the (N+2)-th stage of shift register unit.

In some embodiments, the first clock signal, the second clock signal, the third clock signal and the fourth clock signal have a difference of ¼ period sequentially.

According to a fourth aspect of an embodiment of the present disclosure, there is provided an array substrate, comprising the gate driving circuit as described above.

According to a fifth aspect of an embodiment of the present disclosure, there is provided a display apparatus, comprising the array substrate as described above.

### BRIEF DESCRIPTION OF THE DRAWINGS

In order to make purposes, technical solutions and advantages of embodiments of the present disclosure clearer, technical solutions of embodiments of the present disclosure will be described clearly and completely by combining with accompanying figures of the embodiments of the present disclosure. Obviously, the embodiments described below are a part of embodiments of the present disclosure, but not all the embodiments. Based on the embodiments of the present disclosure described blow, all the other embodiments obtained by those ordinary skilled in the art without paying any inventive labor belong to a scope sought for protection in the present disclosure.

FIG. 1a is a structure schematic diagram of a gate driving circuit and its output signal timing diagram in the prior art;

FIG. 1b is a structure schematic diagram of a shift register unit in the prior art;

FIG. 1c is a signal timing diagram of the shift register unit in the prior art;

FIG. 2 is a structure schematic diagram of one embodiment of a shift register unit provided in the present disclosure;

FIG. 3a is a circuit structure schematic diagram of one embodiment of a shift register unit provided in the present disclosure;

FIG. 3b is a circuit structure schematic diagram of another embodiment of a shift register unit provided in the present disclosure;

FIG. 4 is a signal timing diagram of one embodiment of a shift register unit provided in the present disclosure;

FIG. 5a is an equivalent circuit diagram of one embodiment of a shift register unit provided in the present disclosure;

FIG. 5b is an equivalent circuit diagram of one embodiment of a shift register unit provided in the present disclosure;

FIG. 5c is an equivalent circuit diagram of one embodiment of a shift register unit provided in the present disclosure;

FIG. 5d is an equivalent circuit diagram of one embodiment of a shift register unit provided in the present disclosure;

FIG. 5e is an equivalent circuit diagram of one embodiment of a shift register unit provided in the present disclosure;

FIG. 6 is a flow schematic diagram of one embodiment of a driving method of a shift register unit provided in the present disclosure;

FIG. 7 is a structure schematic diagram of one embodiment of a gate driving circuit provided in the present disclosure; and

FIG. 8 is a schematic diagram of one embodiment of a display apparatus provided in the present disclosure.

### DETAILED DESCRIPTION

In order to make purposes, technical solutions and advantages of the present disclosure clearer. The present disclosure will be further described in detail by combining with specific embodiments and referring to the accompanying figures.

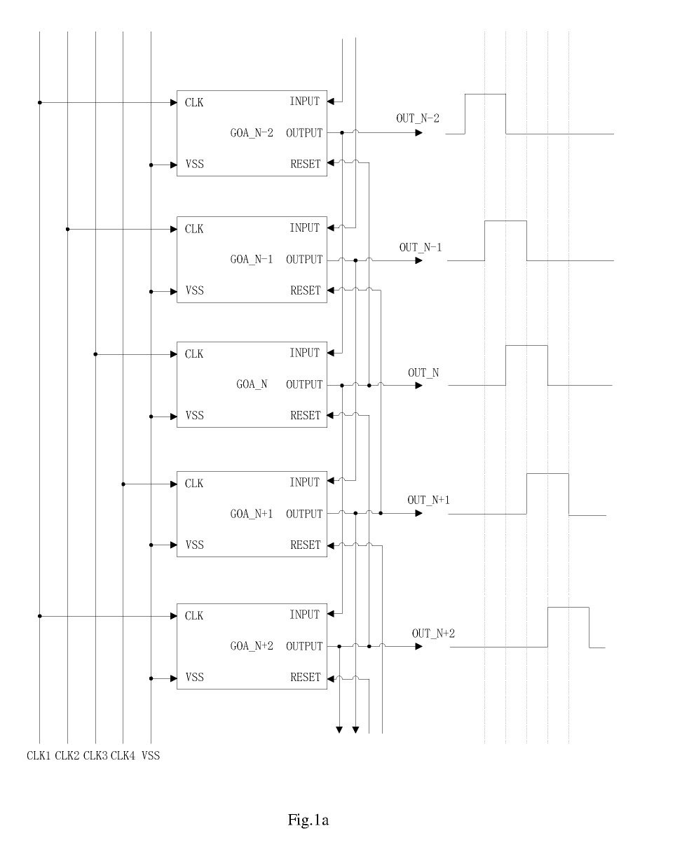

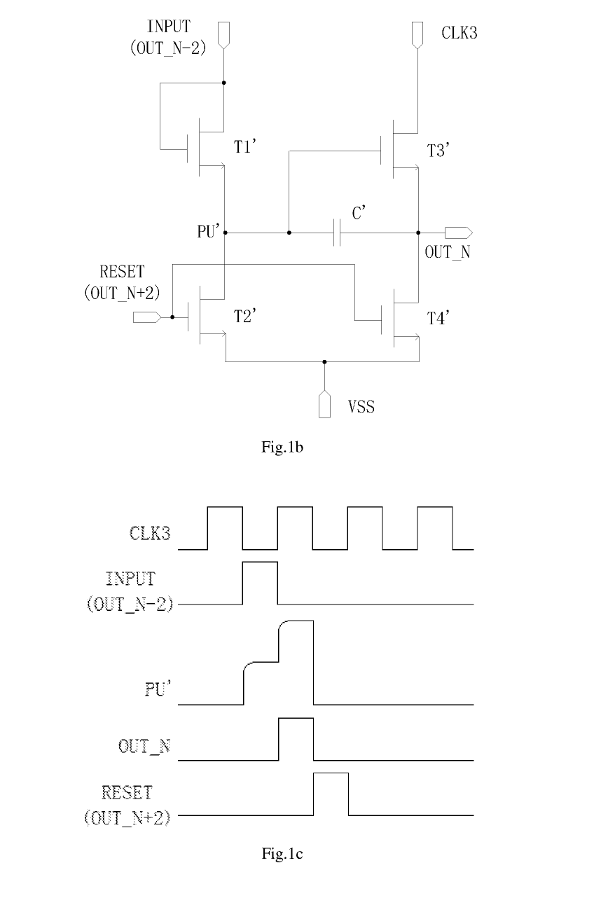

Unless otherwise defined, technical terms or scientific terms used herein shall have general meanings understood by those ordinary skilled in the art of the present disclosure. “First”, “second” and similar words used in the present disclosure do not indicate any sequence, quantity or importance, but are just used to distinguish different components. Also, “include” or “comprise” or other similar words means that a component or an object prior to these words covers an element or an object or its equivalent listed subsequent to these words, without excluding other elements or objects. “Connect” or “connected to” or other similar words is not limited to physical or mechanical connection, but can comprise electrical connection, either direct connection or indirect connection. “Up”, “down”, “left”, “right” and so on are used to indicate relative position relationship. After an absolute position of a described object is changed, then the relative positional relationship is likely to be have a change correspondingly. FIG. 1a shows a structure schematic diagram of a gate driving circuit and an output signal timing diagram of each stage of shift registers in the prior art. The example illustrated in FIG. 1 is a 4CLK pre-charge gate driving circuit.

As shown in FIG. 1a, the 4CLK pre-charge gate driving circuit in the prior art comprises four clock CLK signal lines CLK1-CLK4 and one reset voltage VSS signal line. The gate driving circuit in FIG. 1 is a (N−2)-th stage of shift register unit GOA_N−2, a (N−1)-th stage of shift register unit GOA_N−1, a N-th stage of shift register unit GOA_N, a (N+1)-th stage of shift register unit GOA_N+1, and a (N+2)-th stage of shift register unit GOA_N+2 from up to down sequentially, where N is a positive integer greater than 2; output terminals OUT_N−2, OUT_N−1, OUT_N, OUT_N+1, OUT_N+2 of the shift register units output high level signals in sequence.

FIG. 1b shows a structure schematic diagram of a shift register unit in the prior art, wherein a single shift register unit comprises 4 major operating thin film transistors T1′, T2′, T3′, T4′ and a capacitor C′. Herein, a signal of an input terminal INPUT is input to a pull-up node PU′ through T1′, T3′ is turned on under the control of PU′, and the signal is outputted to the output terminal OUT_N when a signal is input to CLK3. The transistors T2′ and T4′ are used to reset the pull-up node PU′ and the output terminal OUT_N respectively.

A single shift register unit in the prior art generally comprises five signal input and output terminals, i.e., an input terminal INPUT, a clock signal terminal CLK3, a reset terminal RESET, an output terminal OUT_N, a reset voltage terminal VSS. FIG. 1c shows a signal timing sequence of a shift register unit in the prior art. Herein, the accessed signals of the clock signal terminals CLK3 and the reset voltage terminal VSS, which are a clock signal and a low level direct current signal respectively, can be provided by a printed circuit board (PCB) signal source; signals of the input terminal INPUT, the reset terminal RESET, and the output terminal OUT_N are signals connected in cascades between the shift register units, and more importantly, a signal of the output terminal OUT_N is also taken as a gate driving signal.

For the 4CLK pre-charge gate driving circuit structure in the prior art, a signal of the input terminal INPUT of the N-th stage of shift register unit is provided by a signal of an output terminal OUT_N−2 of a (N−2)-th stage, and a signal of the reset terminal RESET of the N-th stage of shift register unit is provided by a signal of an output terminal OUT_N+2 of a (N+2)-th stage; at the same time, a signal of the output terminal OUT_N of the N-th stage can also be taken as a signal of a reset terminal RESET of a (N−2)-th stage and a signal of an input terminal INPUT of a (N+2)-th stage. Additionally, FIG. 1c also shows a pull-up signal timing at the pull-up node PU′.

Thus it can be seen that each gate driving signal of the gate driving circuit in the prior art needs to be provided by one shift register unit, so that the gate driving circuit occupies a relative large space on the whole, which is not beneficial for implementation of a small-size electronic device (for example, a narrow-frame electronic device).

Furthermore, when implementing the present disclosure, inventor(s) of the present disclosure finds that the GOA structure of the prior art has at least following problems:

in the layout of a high-resolution GOA product, it always needs a larger size in a horizontal direction (the long frame of a display panel) because the size in a vertical direction (the short frame of a display panel)is relatively small, that is, the width of the frame of the panel would be increased.

Therefore, according to a first aspect of an embodiment of the present disclosure, there is provided one embodiment of a shift register unit, which can realize a narrow frame.

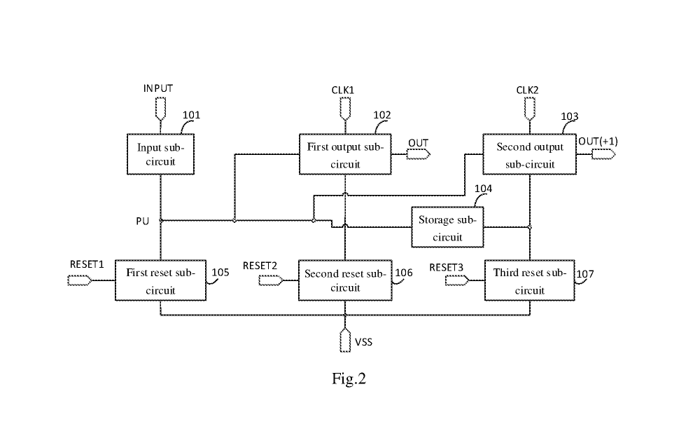

FIG. 2 shows a structure schematic diagram of one embodiment of a shift register unit provided in the present disclosure.

The shift register unit 100 comprises the following.

An input sub-circuit 101, wherein a first terminal of the input sub-circuit is connected to an input signal terminal, and a second terminal of the input sub-circuit is connected to a pull-up node, configured to receive an input signal from an input terminal, output the input signal to the pull-up node, and output a pull-up signal through the pull-up node. For example, as shown in FIG. 2, the input sub-circuit 101 is connected to the input signal terminal INPUT, and the input signal is output to the pull-up node PU through the input sub-circuit 101.

A first output sub-circuit 102, connected to the input sub-circuit 101 and configured to receive a pull-up signal and a first clock signal and output a first output signal according to the pull-up signal and the first clock signal. For example, as shown in FIG. 2, a first terminal of the first output sub-circuit 102 is connected to a first clock signal terminal CLK1, and second terminal thereof is connected to a first output signal terminal OUT. The first clock signal is input to the first output sub-circuit 102 through the first clock signal terminal CLK1, and the first output signal terminal OUT is connected to a gate scanning line (for example, a scanning line of a N-th row) of a corresponding TFT and used to output the first output signal to a gate of the corresponding TFT as a corresponding scanning signal.

A second output sub-circuit 103, connected to the input sub-circuit 101 and configured to receive a pull-up signal and a second clock signal and output a second output signal according to the pull-up signal and the second clock signal. For example, as shown in FIG. 2, a first terminal of the second output sub-circuit 103 is connected to the second clock signal terminal CLK2, and a second terminal thereof is connected to a second output signal terminal OUT(+1). The second clock signal is input to the second output sub-circuit 103 through the second clock signal terminal CLK2, and the second output signal terminal OUT(+1) is connected to a gate scanning line (for example, a scanning line of a (N+1)-th row) of a corresponding TFT and used to output the second output signal to the gate of the corresponding TFT as a corresponding scanning signal.

A storage sub-circuit 104, connected to the input sub-circuit 101 and the second output sub-circuit 103, and configured to store the pull-up signal. As shown in FIG. 2, for example, a first terminal of the storage sub-circuit 103 is connected to the pull-up node PU, and a second terminal thereof is connected to the second output sub-circuit 103.

In some embodiments, the shift register unit 100 further comprises the following.

A first reset sub-circuit 105, connected to a storage sub-circuit 104 and configured to receive a first reset signal and reset the pull-up node PU according to the first reset signal. For example, as shown in FIG. 2, a first terminal of the first reset circuit 105 is connected to a first reset signal terminal RESET1, a second terminal thereof is connected to the pull-up node PU, and a third terminal thereof is connected to the reset voltage terminal VSS. Herein, the first reset sub-circuit 105 receives the first reset signal from the first reset terminal RESET1, and reset the pull-up node PU under the control of the first reset signal.

A second reset sub-circuit 106, connected to the first output sub-circuit 102 and configured to receive a second reset signal and reset the first output signal according to the second reset signal. For example, as shown in FIG. 2, a first terminal of the second reset sub-circuit 106 is connected to a second reset signal terminal RESET2, a second terminal thereof is connected to the first output sub-circuit, and a third terminal thereof is connected to the reset voltage terminal VSS. Herein, the second reset sub-circuit 106 receives the second reset signal from the second reset terminal RESET2, and reset the first output sub-circuit under the control the second reset signal.

A third reset sub-circuit 107, connected to the second output sub-circuit 103, and configured to receive a third reset signal and reset the second output signal according to the third reset signal. For example, as shown in FIG. 2, a first terminal of the third reset sub-circuit 107 is connected to a third reset signal terminal RESET3, a second terminal thereof is connected to the second output sub-circuit, and a third terminal thereof is connected to the reset voltage terminal VSS. Herein, the third reset sub-circuit 107 receives the third reset signal from the third reset terminal RESET3, and resets the second output sub-circuit under the control of the third reset signal.

It can be seen from the above embodiment that the shift register unit provided in the embodiment of the present disclosure adds only one set of output sub-circuit (such as the second output sub-circuit and the third reset sub-circuit) to the existing shift register unit, so that one shift register unit can output two adjacent output signals, so as to greatly reduce the number of TFTs needed by the gate driving circuit and reduce space required for the layout, which is advantageous to realize a design of a smaller-size product.

For example, applying the shift register unit in the above embodiment to the GOA product is capable of reducing the number of TFTs needed by the GOA products greatly and reducing the space required for the layout, which is advantageous to realize the design of a marrow-frame GOA product.

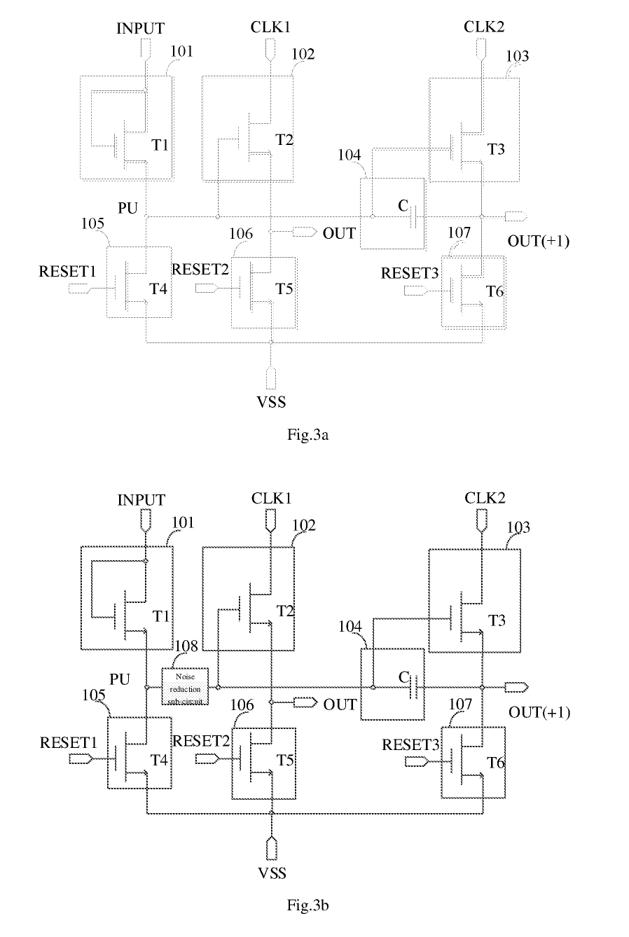

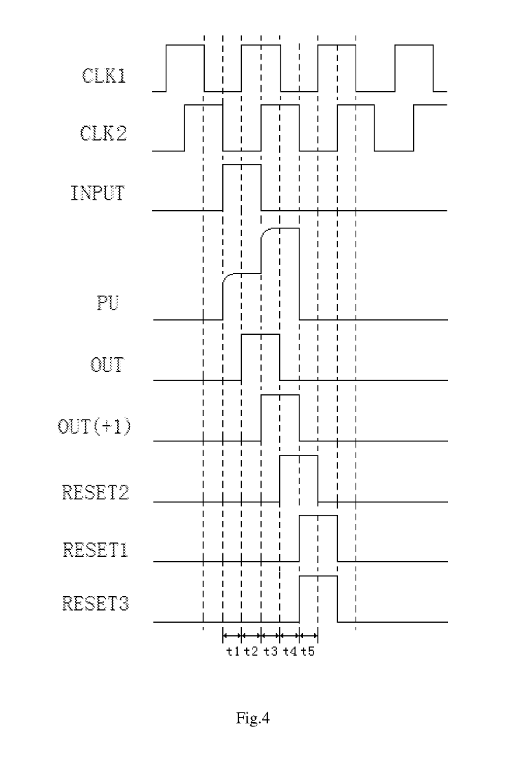

FIG. 3a shows a circuit structure diagram of a shift register unit according to an embodiment of the present disclosure.

In some optional implementations, the input sub-circuit 101 comprises an input transistor T1. A control electrode and a first electrode of the input transistor T1 are connected to the input terminal INPUT and receive the input signal from the input terminal. A second electrode of the input transistor T1 is connected to the pull-up node PU, and is further connected to the first output sub-circuit 102 and the second output sub-circuit 103 through the pull-up node PU respectively. In this way, the function of the input sub-circuit 101 is realized by utilizing the input transistor T1, which is capable of realizing the control of inputting the input signal to the pull-up node PU.

In some optional implementations, the first output sub-circuit 102 comprises a first output transistor T2, wherein a control electrode of the first output transistor T2 is connected to the input sub-circuit 101, a first electrode thereof receives the first clock signal, and a second electrode thereof outputs the first output signal. For example, a first electrode of the first output transistor T2 is connected to the first clock signal terminal CLK1, and configured to receive the first clock signal. A second electrode of the first output transistor T2 is connected to the first output signal terminal OUT, and is used to output the first output signal from the first output signal terminal OUT. The control electrode of the first output transistor T2 is connected to the pull-up node PU, and outputs the first clock signal to the first output terminal as the first output signal under the control of the pull-up node PU. In this way, the first output sub-circuit 102 is realized by adopting the first output transistor T2, which is capable of realizing the control of the first output signal.

In some optional implementations, the second output sub-circuit 103 comprises a second output transistor T3. A control electrode of the second output transistor T3 is connected to the input sub-circuit 101, a first electrode thereof receives the second clock signal, and a second electrode thereof outputs the second output signal. For example, the first electrode of the second output transistor T3 is connected to the second clock signal terminal CLK2, and is used to receive the second clock signal. The second electrode of the second output transistor T3 is connected to the second output signal terminal OUT(+1), and is used to output the second output signal from the second output signal terminal OUT(+1). The control electrode of the second output transistor T3 is connected to the pull-up node PU, and outputs the second clock signal to the second output terminal as the second output signal under the control of the pull-up node PU. In this way, the second output sub-circuit is realized by adopting the second output transistor T3, which is capable of realizing the control of the second output signal.

In some optional implementations, the storage sub-circuit 104 comprises a capacitor C, wherein a first terminal of the capacitor is connected to the input sub-circuit 101, and a second terminal of the capacitor is connected to the second output sub-circuit 103. For example, as shown in FIG. 3a, the first terminal of the capacitor C is connected to the pull-up node PU, and the second terminal thereof is connected to the second output signal terminal OUT(+1). The capacitor C is used to store the pull-up signal. For example, when the input sub-circuit 101 inputs the input signal to the pull-up node PU, since the pull-up node PU is connected to the capacitor C, the input signal can charge the capacitor C, and maintains the potential at the pull-up node PU through the capacitor C. In this way, the storage sub-circuit 104 can be realized by adopting the capacitor C, which is capable of realizing the rise and maintenance of the pull-up signal.

In some optional implementations, the first reset sub-circuit 105 comprises a first reset transistor T4. A control electrode of the first reset transistor T4 receives a first reset signal, a first electrode thereof is connected to the storage sub-circuit 104, and a second electrode thereof receives a reset voltage signal. For example, the control electrode of the first reset transistor T4 is connected to the first reset signal terminal RESET1 and used to receive the first reset signal, the first electrode thereof is connected to the pull-up node PU, and the second electrode thereof is connected to the reset voltage terminal VSS and used to receive the reset voltage signal (optionally, the reset voltage signal is a low level direct current signal, and is provided by a PCB signal source). In this way, the first reset sub-circuit 105 is realized by adopting the first reset transistor T4, which is capable of realizing the control of resetting the pull-up node PU through a first reset signal.

In some optional implementations, the second reset sub-circuit 106 comprises a second reset transistor T5, wherein a control electrode of the second reset transistor receives the second reset signal, a first electrode of the second reset transistor is connected to the first output sub-circuit 102, and a second electrode of the second reset transistor receives the reset voltage signal. For example, the control electrode of the second reset transistor T5 is connected to the second reset signal terminal RESET2 and used to receive the second reset signal. The first electrode of the second reset transistor T5 is connected to the first output signal terminal OUT. The second electrode of the second reset transistor T5 is connected to the reset voltage terminal VSS and used to receive the reset voltage signal (optionally, the reset voltage signal is a low level direct current signal, and is provided by a PCB signal source). In this way, the second reset sub-circuit 106 is realized by adopting the second reset transistor T5, which is capable of realizing the control of resetting the first output signal terminal OUT through the second reset signal.

In some optional implementations, the third reset sub-circuit 107 comprises a third reset transistor T6, wherein a control electrode of the third reset transistor receives a third reset signal, a first electrode of the third reset transistor is connected to the second output sub-circuit 106, and a second electrode of the third reset transistor receives the reset voltage signal. For example, the control electrode of the third reset transistor T6 is connected to the third reset signal terminal RESET3 and used to receive the third reset signal, the first electrode thereof is connected to the second output signal terminal OUT(+1), and the second electrode thereof is connected to the reset voltage terminal VSS and used to receive the reset voltage signal (optionally, the reset voltage signal is a low level direct current signal, and is provided by a PCB signal source). In this way, the third reset sub-circuit 107 is realized by adopting the third reset transistor T6, which is capable of realizing the control of resetting the second output signal terminal OUT(+1) through the third reset signal.

As shown in FIG. 3a, the shift register unit comprises nine input/output terminals: an input signal terminal INPUT, a reset voltage terminal VSS, a first clock signal terminal CLK1, a second clock signal terminal CLK2, a first output signal terminal OUT, a second output signal terminal OUT(+1), a first reset signal terminal RESET1, a second reset signal terminal RESET2 and a third reset signal terminal RESET3. Herein, signals of the first clock signal terminal CLK1, the second clock signal terminal CLK2 and the reset voltage terminal VSS are clock signals and low level direct current signals. The above signals can be provided by the PCB signal source; the input signal terminal INPUT, the first output signal terminal OUT, the second output signal terminal OUT(+1), the first reset signal terminal RESET1, the second reset signal terminal RESET2 and the third reset signal terminal RESET3 are signals connected in cascades between the shift register units, and at the same time, the first output signal terminal OUT and the second output signal terminal OUT(+1) are gate driving signals of gate electrodes of two adjacent rows of respectively.

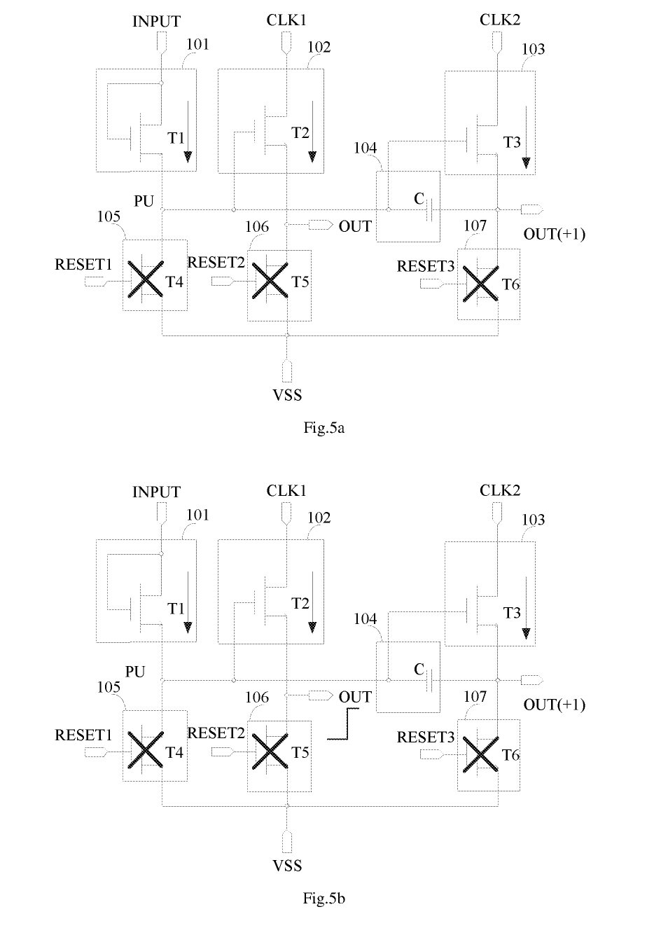

In some optional implementations, by referring to FIG. 4, the first reset signal and the third reset signal are the same reset signal. For example, the first reset signal terminal RESET1 input with the first reset signal and the third reset signal terminal RESET3 input with the third reset signal are connected to a reset signal terminal of a same reset signal. In this way, by sharing a common reset signal, it is capable of reducing the number of devices used in the shift register unit and simplifying the structure design of the shift register unit.

As shown in FIG. 3a, the shift register unit has six TFTs and one capacitor C, wherein the input transistor T1, the first output transistor T2, the first reset transistor T4 and the second reset transistor T5 can use a specification having transistors similar to the existing shift register. In addition, the specification of the second output transistor T3 may be the same as the first output transistor T2, the specification of the third reset transistor T6 may be the same as the second reset transistor T5, and the size of the capacitor C may be the same as that of the capacitor C′ in the existing shift register unit (see FIG. 1b).

By utilizing the shift register unit provided in the embodiment of the present disclosure, the number of TFTs required for the gate driving circuit can be reduced, the space required for the layout can be reduced, which is advantageous for realizing the design of a smaller-size product.

FIG. 3b shows a circuit structure diagram of a shift register unit according to an embodiment of the present disclosure. Structures of the input sub-circuit 101, the first output sub-circuit 102, the second output sub-circuit 103, the storage sub-circuit 104, the first reset sub-circuit 105, the second reset sub-circuit 106 and the third reset sub-circuit 107 as shown in FIG. 3b are the same as the structures as shown in FIG. 3a, and thus no further details are provided herein.

In some optional implementations, a first noise reduction sub-circuit can be disposed between the input sub-circuit 101 and the first output sub-circuit 102, and/or, a second noise reduction sub-circuit can be disposed between the input sub-circuit 101 and the second output sub-circuit 103. For example, as shown in FIG. 3b, functions of the first noise reduction sub-circuit and the second noise reduction sub-circuit are achieved simultaneously by disposing one noise reduction sub-circuit 108. By disposing the noise reduction sub-circuit, it is capable of realizing noise reduction of the pull-up signal at the node PU in a better way, thereby guaranteeing circuit reliability of the gate driving circuit. Optionally, the noise reduction sub-circuit can be designed by referring to the design of the noise reduction circuit in the prior art. The circuit structure of the noise reduction sub-circuit can comprise several TFTs. No limitation is made to the internal structure of the noise reduction circuit.

In some optional implementations, by referring to FIG. 4, the first reset signal and the third reset signal are a same reset signal. For example, the first reset signal terminal RESET1 input with the first reset signal and the third reset signal terminal RESET3 input with the third reset signal are connected to a reset signal terminal of a same reset signal. In this way, by sharing a reset signal, it is capable of reducing the number of devices used in the shift register unit and simplifying the structure design of the shift register unit.

FIG. 4 shows a signal timing schematic diagram of respective input/output terminals of one embodiment of a shift register unit provided in the present disclosure. High levels of clock signals connected to the first clock signal terminal CLK1 and the second clock signal terminal CLK2 sustains for two units of time respectively. Now, an operation principle of the shift register unit according to the principle of the present disclosure will be described by combining with FIGS. 3a, 3b and 4.

In a period of time t1 as shown in FIG. 4, the input signal terminal INPUT receives an input signal at a high level. The input sub-circuit 101 inputs the input signal to the pull-up node PU, and pulls up the potential of the node PU. For example, as shown in FIG. 3a, both the control terminal and the first electrode of the input transistor T1 are connected to the input terminal INPUT, so that the input transistor T1 will be turned on under the control of the input signal and input the input signal to the pull-up node PU. The high level of the pull-up node PU will turn on the first output transistor T2 and the second output transistor T3.

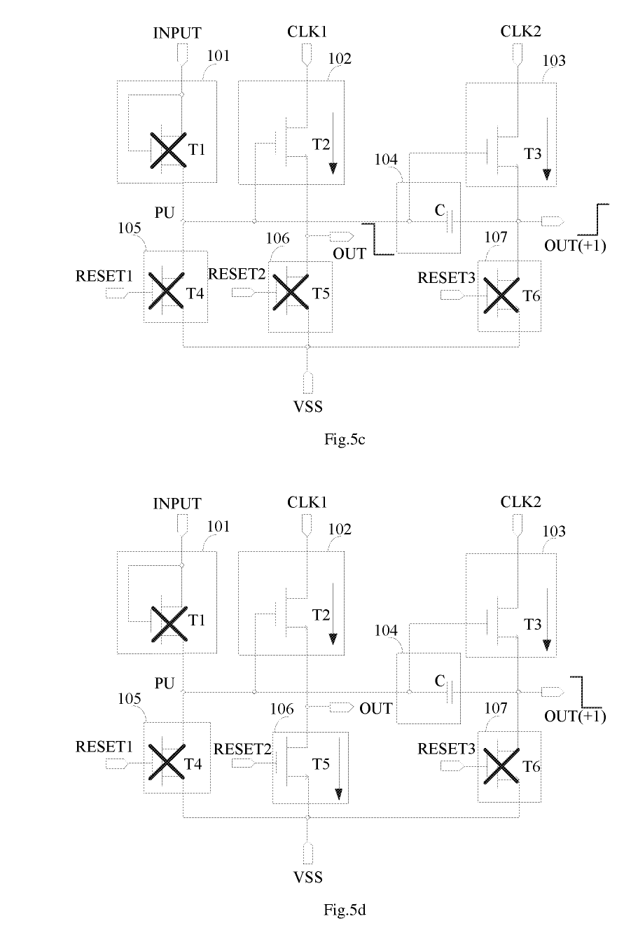

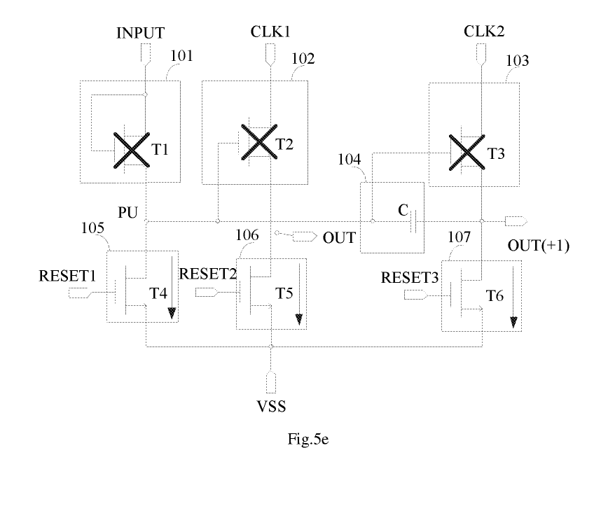

FIG. 5a shows an equivalent circuit diagram of a shift register in the period of time t1. During the period of time t1, the input transistor T1, the first output transistor T2, and the second output transistor T3 are turned on. The first reset transistor T4, the second reset transistor T5, and the third reset transistor T6 are turned off.

Returning to FIG. 4, during a subsequent time of one unit (period of time t2), the high level of the first clock signal connected to the first clock signal terminal CLK1 comes, the first output signal terminal OUT is charged through the first output transistor T2, and the first output signal terminal OUT starts to output the high level.

FIG. 5b shows an equivalent circuit diagram of a shift register during the period of time t2. During the period of time t2, the input transistor T1, the first output transistor T2, and the second output transistor T3 are turned on. The first reset transistor T4, the second reset transistor T5, and the third reset transistor T6 are turned off. The first output signal terminal OUT outputs a high level.

Returning to FIG. 4, during a subsequent time of one unit (period of time t3), the input signal at the high level is not input to the input terminal INPUT, and the input transistor T1 is turned off. The high potential of the second clock signal connected to the second clock signal terminal CLK2 comes, the second output signal terminal OUT(+1) is charged through the second output transistor T3, and the second output signal terminal OUT(+1) starts to output the high level. At this time, due to the bootstrapping effect of the capacitor C, the high potential at the node PU would be raised to two times of the original potential, and the first output signal terminal OUT would also continue outputting the high level for a time of one unit.

FIG. 5c shows an equivalent circuit diagram of a shift register during the period of time t3. During the period of time t3, the input transistor T1 is turned off. The first output transistor T2, and the second output transistor T3 are turned on. The first reset transistor T4, the second reset transistor T5, and the third reset transistor T6 are turned off. The first output signal terminal OUT and the second output signal terminal OUT(+1) output a high level.

Returning to FIG. 4, after the first output signal terminal OUT output high level for a time of two units totally, in the period of time t4, the high level of the second reset signal of the second reset signal terminal RESET2 comes, the second reset transistor T5 is turned on under the control of the second reset signal, and resets the first output signal terminal OUT according to the low level reset signal of the reset voltage terminal VSS, and the high level output by the first output signal terminal OUT ends up.

FIG. 5d shows an equivalent circuit diagram of a shift register during a period of time t4. During the period of time t4, the input transistor T1 is turned off. The first output transistor T2 and the second output transistor T3 are turned on. The first reset transistor T4 and the third reset transistor T6 are turned off. The second reset transistor T5 is turned on. At this time, the second output signal terminal (+1) outputs the high level, and the first output signal terminal OUT is reset under the control of the second reset signal.

Returning to FIG. 4, for a subsequent time of one unit (period of time t5), the high level of the third reset signal of the third reset signal terminal RESET3 comes, and the third reset transistor T6 resets the second output signal terminal by utilizing the low level reset voltage signal connected to the reset voltage terminal VSS under the control of the third reset signal. At the same time, the high level of the first reset signal of the first reset signal terminal RESET1 comes, the first reset terminal T4 resets the pull-up node PU by utilizing the low level reset voltage signal connected to the reset voltage terminal VSS under the control of the first reset signal.

It can be seen from the above embodiment that the shift register unit provided according to the embodiment of the present disclosure only adds to dispose the second output transistor and the third reset transistor to the original shift register unit circuit, so that one shift register unit can output two adjacent output signals, which are used to drive gates of adjacent rows respectively, thereby greatly reducing the number of TFTs required for the gate driving circuit and reducing the space required for the layout, which is advantageous to realize the design of a smaller-size product.

It needs to specify that transistors in the above respective embodiments can be any type of transistor which can be applied to the shift register at present or in future, for example, one or more of a polysilicon thin film transistor, an amorphous-silicon thin film transistor, an oxide thin film transistor and a organize thin film transistor. The present disclosure does not limit the type of the adopted transistors. “Control electrode” mentioned in the present embodiment can particularly refer to a gate electrode or a base electrode of the transistor. “First electrode” can particularly refer to a source or an emitting electrode of the transistor. The corresponding “second electrode” can particularly refer to a drain or a collecting electrode of the transistor. Of course, those skilled in the art should know that the “first electrode” and “second electrode” can be exchanged with each other.

Additionally, in the above embodiment, the input transistor T1, the first output transistor T2, the second output transistor T3, the first reset transistor T4, the second reset transistor T5 and the third reset transistor T6 are N type transistors. It is a preferred solution being convenient for implementation in the present embodiment, and would not limit the technical solution of the present disclosure. Those skilled in the art should know that simply changing the types (type N or type P) of respective transistors and changing positive and negative electrodes of output voltages of the respective power supply terminals and control signal lines so as to realize the technical solution of performing the same turn-on or turn-off operations on the respective transistors in the present embodiment belongs to the scope sought for protection in the present application. Specific situations are not illustrated one by one herein.

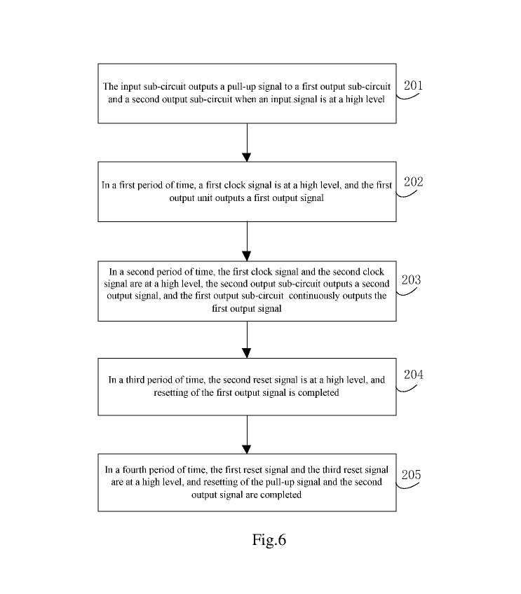

FIG. 6 is a flow schematic diagram of one embodiment of a driving method of a shift register unit provided in the present disclosure.

As shown in FIG. 6, by combining with FIG. 4, the driving method of the shift register unit is used to drive the shift register unit in the embodiment as described above, comprising:

Step 201: outputting a pull-up signal to a first output sub-circuit 102 and a second output sub-circuit 103 through an input sub-circuit 101 when an input signal is at a high level;

Step 202: in a first period of time, a first clock signal is at a high level, and the first output sub-circuit 102 outputs a first output signal;

Step 203: in a second period of time, the first clock signal and the second clock signal are at a high level, the second output sub-circuit 103 outputs a second output signal, and the first output sub-circuit 102 continuously outputs the first output signal;

Step 204: in a third period of time, the second reset signal is at a high level, and resetting of the first output signal is completed;

Step 205: in a fourth period of time, the first reset signal and the third reset signal are at a high level, and resetting of the pull-up signal and the second output signal are completed.

It can be seen from the above embodiments that under the premise of making improvements to the circuit of the shift register unit, through the design of signals of respective input terminals of the shift register unit, the driving method of the shift register unit provided in the embodiment of the present disclosure makes one shift register unit output two adjacent output signals, which are used to drive gates of two adjacent rows respectively, so that the number of TFTs required for the gate driving circuit is reduced greatly, and the space required for the layout is reduced, which is advantageous to realize the design of a smaller-size product.

Optionally, the first reset signal and the third reset signal are the same reset signal. By sharing a reset signal, it is capable of reducing devices and simplifying the structure design of the shift register unit.

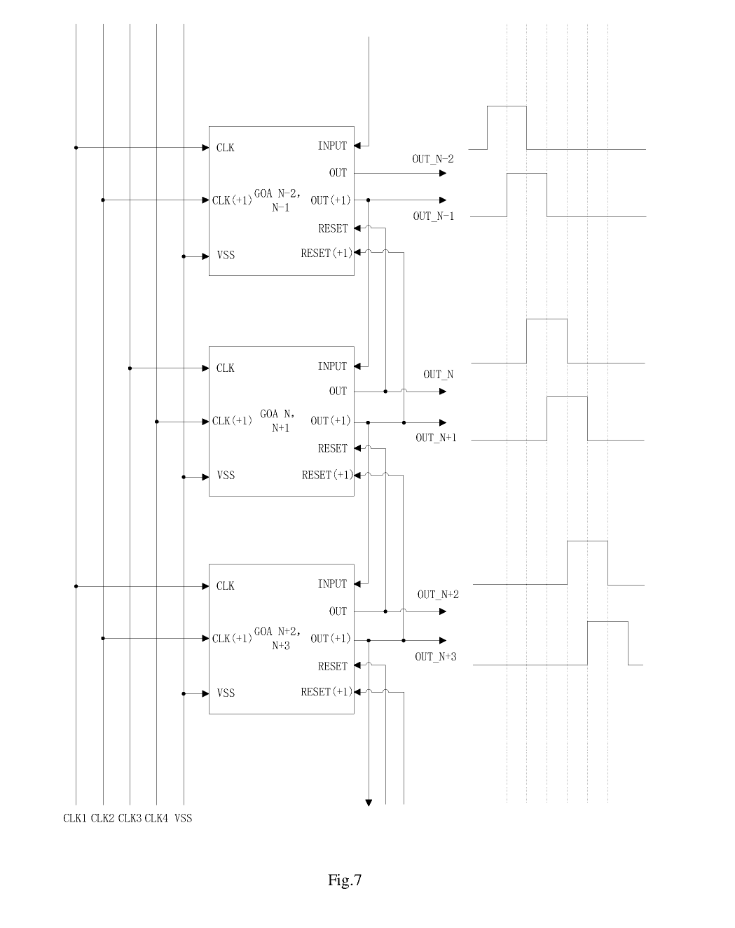

FIG. 7 is a structure schematic diagram of one embodiment of a gate driving circuit provided in the present disclosure.

The gate driving circuit comprises at least two shift register units connected in cascades as described in any one of the embodiments.

Input signal terminals INPUT of a N-th stage of shift register units GOA_N, N+1 are connected to second output signal terminals OUT(+1) of a (N−1)-th stage of shift register units GOA_N−2, N−1, first clock signal terminals CLK and second clock signal terminals CLK(+1) of the N-th stage of shift register units GOA_N, N+1 are connected to the first clock signal CLK1 and the second clock signal CLK2, first reset signal terminals and third reset signal terminals RESET(+1) of the N-th stage of shift register units GOA_N, N+1 are connected to second output signal terminals OUT(+1) of the (N+1)-th stage of shift register units GOA_N+2, N+3, and second reset signal terminals RESET of the N-th stage of shift register units GOA_N, N+1 are connected to first output signal terminals OUT of the (N+1)-th stage of shift register units GOA_N+2, N+3.

Input signal terminals INPUT of the (N+1)-th stage of shift register units GOA_N+2, N+3 are connected to second output signal terminals OUT(+1) of the N-th stage of shift register units GOA_N, N+1, first clock signal terminals CLK and second clock signal terminals CLK(+1) of the (N+1)-th stage of shift register units GOA_N+2, N+3 are connected to the third clock signal CLK3 and the fourth clock signal CLK4 respectively, first reset signal terminals and third reset signal terminals RESET(+1) of the (N+1)-th stage of shift register units GOA_N+2, N+3 are connected to a second output signal terminal OUT(+1) of a (N+2)-th stage of shift register unit (not shown), and a second reset signal terminal RESET of a (N+1)-th stage of shift register unit is connected to a first output signal terminal OUT of a (N+2)-th stage of shift register unit (not shown).

Herein, the first clock signal, the second clock signal, the third clock signal and the fourth clock signal have a difference of ¼ period sequentially. At the same time, a signal timing of each stage of shift register unit can refer to the timing in FIG. 4.

It can be seen from the above embodiment that through the design of connection of the clock signal lines and the signal terminals of the shift register units connected in cascades, the gate driving circuit provided in the embodiment of the present disclosure makes that one shift register unit can output two adjacent output signals, so that the number of TFTs required for the GOA products is reduced greatly, and the space required for the layout is reduced, which is advantageous to realize the design of a smaller-size GOA product.

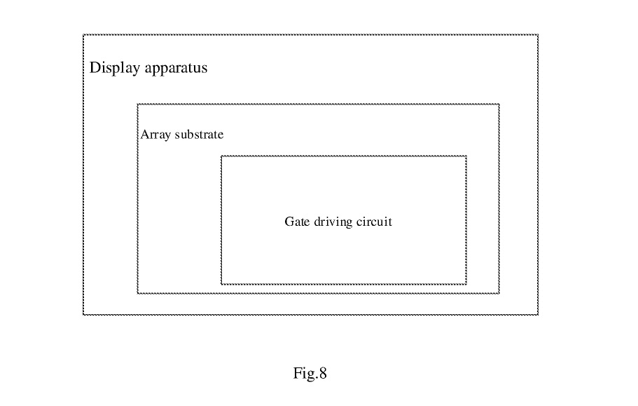

FIG. 8 is a schematic diagram of one embodiment of a display apparatus provided in the present disclosure.

The display apparatus shown in FIG. 8 can comprise an array substrate, wherein the array substrate can comprise the gate driving circuit as described in any one of previous embodiments.

It needs to specify that the display apparatus in the present embodiment can be any product or component having a function of displaying such as an electronic paper, a mobile phone, a tablet computer, a television set, a notebook computer, a digital photo frame, a navigator, etc.

It can be seen from the above embodiment that the array substrate and the display apparatus provided in the present disclosure only adds the second output sub-circuit and the third reset sub-circuit to the original shift register unit circuit, so that one shift register unit can output two adjacent output signals, thereby reducing the number of TFTs required for the gate driving circuit greatly and reducing the space required for the layout, which is advantageous to realize the design of a smaller-size product.

The embodiment of the present disclosure will be compared with the prior art briefly, so as to clarify the technical effect produced by the present disclosure.

It is assumed that the existing shift register unit comprises M (M>4, common values are 9, 10, 12, 16, etc.) TFTs, and one capacitor C. Then, the structure of the gate driving circuit comprising one ultra-high resolution display and a single gate electrode generally includes 2160*M TFTs and 2016 capacitors.

After the gate driving circuit provided in the embodiment of the present disclosure is adopted, no change is made to the noise reduction structure with respect to the internal structure of the shift register unit. Two output signals can be output only if the circuit structure is adjusted, and at the same time two TFTs are added within one shift register unit, that is, it needs 2*M TFTs and 2 capacitors C for the structure of the original shift register unit to output two adjacent gate signals. The structure of the shift register unit of the present disclosure only needs (M+2) TFTs and one capacitor C. In this way, the structure of the gate driving circuit comprising one ultra-high resolution display and a single gate only needs to include 1080*(M+2) TFTs and 1080 capacitors.

Based on the comparison, it can be seen that by adopting the shift register unit provided in the embodiment of the present disclosure, the gate driving circuit and the corresponding array substrate and display apparatus comprising the gate driving circuit, it is capable of greatly reducing the number of TFTs and reducing the number of capacitors by half, which greatly saves the wiring space of the gate driving circuit and is advantageous to realize the design of a smaller-size product.

Those ordinary skilled in the art should understand that discussion for any one of the embodiments described above are just for illustration, but does not suggest the scope (including the claims) of the present disclosure is limited to these examples; according to the concept of the present disclosure, the above embodiments or technical features among different embodiments can be combined, steps thereof can be implemented in any random sequence, and many other alternations of different aspects of the present disclosure as described above exist but are not provided in the details for the purpose of simple and clear.

Additionally, for the purpose of simplifying description and discussion, and in order to make the present disclosure not difficult to be understood, the commonly known power supply/ground connection with the integrated circuit (IC) and other components can be shown or cannot be shown in the figures. Additionally, the apparatus can be shown in a form of a block diagram, so as to avoid the present disclosure from being understood with difficulty, and also the following fact is considered, that is, details about the implementations of these block diagram apparatuses are highly dependent upon a platform on which the present disclosure is going to be implemented (i.e., these details shall completely fall into the understanding scope of those skilled in the art). In the case of stating specific details (for example, circuit) to describe the exemplary embodiments of the present disclosure, it is obvious for those skilled in the art that the present disclosure can be implemented without these specific details or can be implemented if these specific details have some changes. Therefore, these descriptions shall be regarded as illustrative but not restrictive.

Although the present disclosure has been described by combining with specific embodiments of the present disclosure, according to the previous descriptions, many replacements, alternations and modifications of these embodiments are obvious for those ordinary skilled in the art. For example, other memory architectures (for example dynamic RAM (DRAM)) can use the discussed embodiments.

Those skilled in the art can clearly know that the present disclosure can be realized with the aid of software and necessary general hardware, and of course, can be realized by means of a specific hardware. However, in many occasions, software and necessary general hardware are likely to be preferred implementations. Based on such understanding, the technical solutions of the present disclosure are reflected by means of software, hardware, firmware or any combination of the above. The computer software product is stored in a readable storage medium such as a magnetic storage medium (for example, hard disk) or an electronic storage medium (for example, ROM, a flash memory), etc., comprising several instructions which are used to enable one computer device (it may be a computer, a server, or a network device, etc.) to implement the method according to respective embodiments of the present disclosure.

The embodiments of the present disclosure aim to cover all replacements, alternations and modifications falling into the general scope of the claims. Therefore, any omission, alternation, equivalent replacement, or improvement and so on within the spirit and principle of the present disclosure shall be included within the protection scope of the present disclosure.

1. A shift register unit, comprising:
an input sub-circuit, wherein a first terminal of the input sub-circuit is connected to an input terminal and a second terminal of the input sub-circuit is connected to a pull-up node, for receiving an input signal from the input terminal, outputting the input signal to the pull-up node, and outputting a pull-up signal through the pull-up node;
a first output sub-circuit, wherein a first terminal of the first output sub-circuit is connected to a first output signal terminal, a second terminal of the first output sub-circuit is connected to a first clock signal terminal, and a third terminal of the first output sub-circuit is connected to the pull-up node, for receiving the pull-up signal and a first clock signal, and outputting a first output signal from the first output signal terminal according to the pull-up signal and the first clock signal;
a second output sub-circuit, wherein a first terminal of the second output sub-circuit is connected to a second output signal terminal, a second terminal of the second output sub-circuit is connected to a second clock signal terminal, and a third terminal of the second output sub-circuit is connected to the pull-up node, for receiving the pull-up signal and a second clock signal, and outputting a second output signal from the second output signal terminal according to the pull-up signal and the second clock signal;
a storage sub-circuit, wherein a first terminal of the storage sub-circuit is connected to the pull-up node, a second terminal of the storage sub-circuit is connected to the second output sub-circuit, for storing the pull-up signal.

2. The shift register unit according to claim 1, further comprising:
a first reset sub-circuit, wherein a first terminal of the first reset sub-circuit is connected to the pull-up node, a second terminal of the first reset sub-circuit is connected to a first reset terminal, and a third terminal of the first reset sub-circuit is connected to a reset voltage terminal, for receiving a first reset signal from the first reset terminal, and resetting the pull-up node according to the first reset signal.

3. The shift register unit according to claim 2, further comprising:
a second reset sub-circuit, wherein a first terminal of the second reset sub-circuit is connected to the first output sub-circuit, a second terminal of the second reset sub-circuit is connected to a second reset terminal, and a third terminal of the second reset sub-circuit is connected to a reset voltage terminal, for receiving a second reset signal from the second reset terminal, and resetting the first output sub-circuit according to the second reset signal.

4. The shift register unit according to claim 3, further comprising:
a third reset sub-circuit, wherein a first terminal of the third reset sub-circuit is connected to the second output sub-circuit, a second terminal of the third reset sub-circuit is connected to a third reset terminal, and a third terminal of the third reset sub-circuit is connected to a reset voltage terminal, for receiving a third reset signal from the third reset terminal, and resetting the second output sub-circuit according to the third reset signal.

5. The shift register unit according to claim 1, wherein the input sub-circuit comprises an input transistor, wherein a control electrode and a first electrode of the input transistor are connected to the input terminal and receive the input signal through the input terminal, and a second electrode of the input transistor is connected to the pull-up node.

6. The shift register unit according to claim 1, wherein the first output sub-circuit comprises a first output transistor, wherein a control electrode of the first output transistor is connected to the pull-up node, a first electrode of the first output transistor is connected to the first clock signal terminal and receives the first clock signal, and a second electrode of the first output transistor is connected to the first output signal terminal and outputs the first output signal.

7. The shift register unit according to claim 1, wherein the second output sub-circuit comprises a second output transistor, wherein a control electrode of the second output transistor is connected to the pull-up node, a first electrode of the second output transistor is connected to the second clock signal terminal and receives the second clock signal, and a second electrode of the second output transistor is connected to the second output signal terminal and outputs the second output signal.

8. The shift register unit according to claim 1, wherein the storage sub-circuit comprises a capacitor, wherein a first terminal of the capacitor is connected to the pull-up node, and a second terminal of the capacitor is connected to the second output signal terminal.

9. The shift register unit according to claim 4, wherein the first reset sub-circuit comprises a first reset transistor, wherein a control electrode of the first reset transistor is connected to the first reset terminal and receives the first reset signal, a first electrode of the first reset transistor is connected to the storage sub-circuit, and a second electrode of the first reset transistor is connected to a reset voltage terminal and receives a reset voltage signal; and/or,
the second reset sub-circuit comprises a second reset transistor, wherein a control electrode of the second reset transistor is connected to the second reset terminal and receives the second reset signal, a first electrode of the second reset transistor is connected to the first output signal terminal, and a second electrode of the second reset transistor is connected to the reset voltage terminal and receives the reset voltage signal; and/or,
the third reset sub-circuit comprises a third reset transistor, wherein a control electrode of the third reset transistor is connected to the third reset terminal and receives the third reset signal, a first electrode of the third reset transistor is connected to the second output signal terminal, and a second electrode of the third reset transistor is connected to the reset voltage terminal and receives the reset voltage signal.

10. The shift register unit according to claim 1, wherein a noise reduction sub-circuit is disposed between the input sub-circuit and the first output sub-circuit, and/or, a second noise reduction sub-circuit is disposed between the input sub-circuit and the second output sub-circuit.

11. The shift register unit according to claim 4, wherein the first reset signal and the third reset signal are a same reset signal.

12. A driving method of a shift register unit for driving the shift register unit according to claim 1, comprising:
outputting a pull-up signal to the first output sub-circuit and the second output sub-circuit through the input sub-circuit when the input signal is at a turn-on level;
in a first period of time, the first clock signal is at a turn-on level, and the first output sub-circuit outputs the first output signal;
in a second period of time, the first clock signal and the second clock signal are at a turn-on level, the second output sub-circuit outputs the second output signal, and the first output sub-circuit continuously outputs the first output signal.

13. The driving method according to claim 12, comprising:
in a third period of time, a second reset signal is at a turn-on level, and resetting of the first output signal is completed.

14. The driving method according to claim 13, further comprising:
in a fourth period of time, a first reset signal and a third reset signal are at a turn-on level, and resetting of the pull-up signal and the second output signal is completed.

15. The driving method according to claim 14, wherein the first reset signal and the third reset signal are a same reset signal.

16. A gate driving circuit, comprising at least two shift register units according to claim 1 connected in cascades;
an input signal terminal of a N-th stage of shift register unit is connected to a second output signal terminal of a (N−1)-th stage of shift register unit, a first clock signal terminal and a second clock signal terminal of the N-th stage of shift register unit are connected to a first clock signal and a second clock signal respectively, a first reset signal terminal and a third reset signal terminal of the N-th stage of shift register unit are connected to a second output signal terminal of a (N+1)-th stage of shift register unit, and a second reset signal terminal of the N-th stage of shift register unit is connected to a first output signal terminal of the (N+1)-th stage of shift register unit.

17. The gate driving circuit according to claim 16, wherein an input signal terminal of the (N+1)-th stage of shift register unit is connected to a second output signal terminal of the N-th stage of shift register unit, a first clock signal terminal and a second clock signal terminal of the (N+1)-th stage of shift register unit are connected to a third clock signal and a fourth clock signal respectively, a first reset signal terminal and a third reset signal terminal of the (N+1)-th stage of shift register unit is connected to a second output signal terminal of a (N+2)-th stage of shift register unit, and a second reset signal terminal of the (N+1)-th stage of shift register unit is connected to a first output signal terminal of the (N+2)-th stage of shift register unit.

18. The gate driving circuit according to claim 17, wherein the first clock signal, the second clock signal, the third clock signal and the fourth clock signal have a difference of ¼ period sequentially.

19. An array substrate, comprising the gate driving circuit according to claim 16.

20. A display apparatus, comprising the array substrate according to claim 19.
